(19) United States
(12) Patent Application Publication
(10) Pub. No.: US 2020/0176352 A1
(43) Pub. Date: Jun. 4, 2020

(54) DIE BACKSIDE STRUCTURES FOR ENHANCING LIQUID COOLING OF HIGH POWER MULTI-CHIP PACKAGE (MCP) DICE

(71) Applicant: Intel Corporation, Santa Clara, CA (US)

(72) Inventors: Je-Young CHANG, Phoenix, AZ (US); Chandra M. JHA, Chandler, AZ (US); Shankar DEVASENATHIPATHY, Tempe, AZ (US); Feras EID, Chandler, AZ (US); John C. JOHNSON, Phoenix, AZ (US)

(21) Appl. No.: 16/612,340

(22) PCT Filed: Jun. 30, 2017
(86) PCT No.: PCT/US2017/040286

§ 371 Date: Nov. 8, 2019

(51) Int. Cl. H01L 23/427; H01L 23/26; H01L 23/373; H01L 23/433; H01L 21/48; F28D 15/02

(52) U.S. Cl. CPC H01L 23/427; H01L 23/26; F28D 15/0275; H01L 23/4334; H01L 21/4882; H01L 23/3733

(57) ABSTRACT

An integrated circuit die includes a device side and a backside opposite the device side, wherein the backside includes a heat transfer enhancement configuration formed therein or a heat transfer enhancement structure formed thereon each of which enhance a heat transfer area or a boiling nucleation site density over a planar backside surface. A method of forming an integrated circuit assembly includes disposing a heat exchanger on a multi-chip package, the multi-chip package including at least one integrated circuit die including a device side and an opposite backside includes a heat transfer enhancement configuration formed therein or a heat enhancement structure formed thereon; and contacting the backside of the at least one integrated circuit die with water or other cooling fluids, such as a mixture of water and antifreeze, alcohol, inert fluorinated hydrocarbon, helium, and/or other suitable cooling fluid (either liquid or gas).

### BACKGROUND

### Field

Integrated circuit devices and techniques and configurations for the removal of heat from multi-chip packages.

### Description of Related Art

With increasing thermal demands of high-performance multi-chip products, liquid cooling has been explored in various forms, both at system-level and at package level (e.g., within an integrated heat spreader (IHS) lid). A key driver for package-level liquid cooling is to eliminate thermal interface material (TIM2) thermal resistance thereby improving cooling capability over system-level liquid cooling technology.

### BRIEF DESCRIPTION OF THE DRAWINGS

FIG. 1 shows a side view of a generic multi-chip central processing unit (CPU) package.

FIG. 2 shows an example of an integrated circuit die including a device side and a backside with a heat transfer enhancement structure formed on the backside of the die.

FIG. 3 shows another embodiment of an integrated circuit die including a heat transfer enhancement structure.

FIG. 4 shows another embodiment of an integrated circuit die including a heat transfer enhancement structure.

FIG. 5 shows another embodiment of an integrated circuit die including a heat transfer configuration formed in a backside thereof.

FIG. 6 shows a further embodiment of a die including a heat transfer configuration formed in a backside thereof.

FIG. 7 shows an embodiment of an integrated circuit assembly.

FIG. 8 shows another embodiment of an integrated circuit assembly.

FIG. 9 illustrates an embodiment of a computing device.

### DETAILED DESCRIPTION

Techniques and configurations for heat removal from an integrated circuit die such as a die in a multi-chip package are disclosed. In one embodiment, an integrated circuit die includes a device side and an opposite backside wherein the backside includes a heat transfer configuration formed therein or a heat enhancement structure formed thereon each of which enhances heat transfer area or boiling nucleation site density over a planar backside surface.

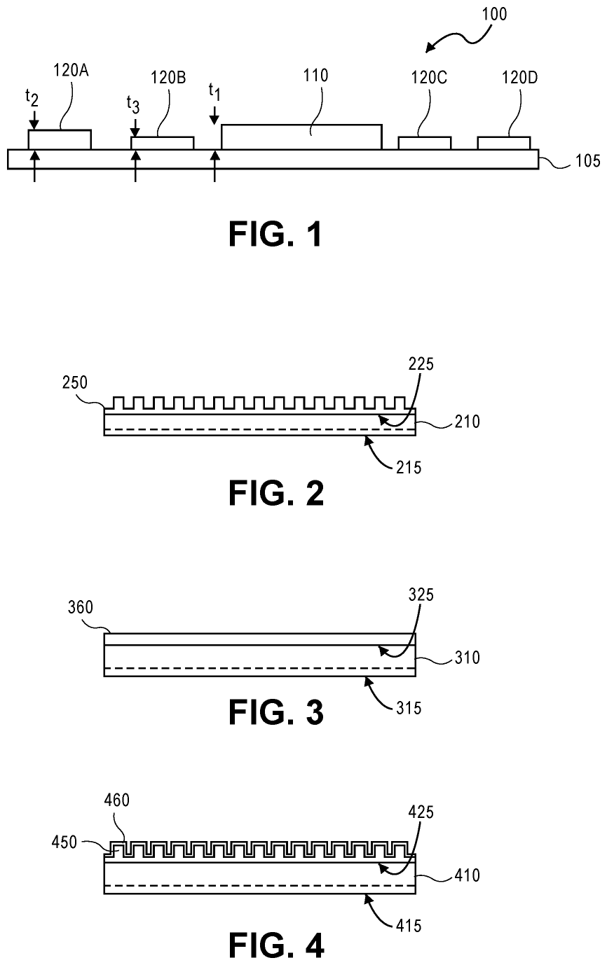

FIG. 1 shows a side view of a generic multi-chip central processing unit (CPU) package. Package 100 includes die 110 disposed on package substrate 105. In one embodiment, die 110 is a central processing unit. In this embodiment, package 100 also includes secondary dies 120A, 120B, 120C and 120D. Secondary dies 120A-120D are representatively memory chips, companion processor chips, communication chips, application specific chips (ASIC), etc. Each of die 110 (the primary device) and dies 120A-120D (the secondary devices) are connected in a planar array to package substrate 105. In one embodiment, a thickness (z-dimension) of the one or more secondary devices (dies 120A-120D) is different than a thickness (z-dimension) of die 110. In another embodiment, a z-dimension thickness of one or more secondary devices is different than die 110 and one or more other secondary devices. FIG. 1 representatively shows die 110 having a thickness, t₁; die 120A having a thickness, t₂, and die 120B having a thickness, t₃. In this embodiment, t₁ is greater than t₂ or t₃ and t₂ is greater than t₃. In another embodiment, a thickness of each of the primary device (die 110) and secondary devices (dies 120A-120D) is similar.

In one embodiment, each of die 110 and dies 120A-120D includes a device side including a number of, for example, transistor devices formed therein and thereon. Each die is connected to package substrate 105 in a device side down configuration through, for example, controlled collapse chip connections. In one embodiment, at least one of die 110 and dies 120A-120D and, in another embodiment, each of die 110 and dies 120A-120D, has a die backside opposite of the device side that includes a heat transfer enhancement configuration formed therein or a heat transfer enhancement structure formed thereon.

FIG. 2 shows an example of an integrated circuit die including a device side and a backside with a heat transfer enhancement structure formed on the backside of the die. Referring to FIG. 2, the figure shows die 210 that is, for example, a semiconductor integrated circuit chip such as a primary device or a secondary device in a multi-chip package. Die 210 includes device side 215 including a number of transistors and possibly other devices formed therein or thereon. Opposite device side 215 is backside 225. Backside 225 defines a generally planar surface to which heat transfer enhancement structure 250 is connected. Heat transfer enhancement structure 250, in this embodiment, is a thermally conductive material such as a metal material (e.g., copper or other thermally conductive metal or metals). Heat transfer enhancement structure 250 includes a first surface that is generally planar and directly connected to backside surface 225 of die 210. An opposite surface of heat transfer enhancement structure 250 has a greater surface area than the planar surface. In this embodiment, the opposite surface is shown as a number of projecting pillars or fins. Heat transfer enhancement structure 250 made of, for example, copper may be formed by a plating process wherein, for example, backside surface 225 of die 210 is directly seeded with a seed material and followed by plating of a copper layer to directly interface with backside surface 225 of die 210. The copper layer may be patterned by, for example, lithographic means into a desired structure to increase a surface area of the heat transfer enhancement structure 250. Such pillars are representative of one configuration of an increased surface area. Other configurations are also contemplated. Further, heat transfer enhancement structure 250 is shown as a series of continuous pillars. It is appreciated that such pillars need not be continuous, either across backside surface 225 of die 210 in length or width. In another embodiment, such pillars do not have a connecting base as shown but may stand alone with respect to one another. In a further embodiment, heat transfer enhancement structure 250 may be attached to backside surface 225 of die 210 with an adhesive or by thermal bonding. In such an embodiment, there is no thermal interface material between the backside surface and the heat transfer enhancement structure.

FIG. 3 shows another embodiment of an integrated circuit die including a heat transfer enhancement structure. Referring to FIG. 3, die 310 includes device side 315 including a number of transistors or other devices and an opposite backside surface 325. Directly connected to a die backside surface, in this embodiment, is heat transfer enhancement structure 360. Heat transfer enhancement structure 360, in this embodiment, is a porous coating layer. A porous coating layer, in this embodiment, includes any porous material (e.g., a microporous material) that is thermally conductive. Representative material includes silicon or a porous metal or any other thermally conductive material including a metal that may be deposited as, for example, particles to form a microporous coating. For example, a metal such as copper may be reduced to particulate form by way of a sintering process and then deposited on a surface of backside 325 of die 310. A silicon porous coating may representatively be formed by a sol gel process. In another embodiment, the microporous coating includes a material that is functionalized to increase a hydrophilicity of the layer. In one embodiment, the hydrophilicity may be increased by adding a hydrophilic coating such as a self-assembled monolayer to the coating (e.g., coating particles) or the layer may be functionalized to modify the exposed surface (modify a surface chemistry) by the addition of hydroxyl groups to the layer. In one embodiment, the porous coating has a thickness on the order of less than one millimeter.

FIG. 4 shows another embodiment of an integrated circuit die including a heat transfer enhancement structure. Referring to FIG. 4, die 410 includes device side 415 including a number of, for example, transistor devices and opposite backside 425. Disposed on a generally planar surface of backside 425 is a heat transfer enhancement structure. In this embodiment, the heat transfer enhancement structure includes a first structure and a second structure. First structure 450 is, for example, a thermally conductive material such as a metal having a first surface directly in contact with a surface of die backside 425 and an opposite second surface having a greater surface area than the planar surface. In one embodiment, heat transfer enhancement structure 450 is a thermally conductive material such as a metal patterned into a number of pillars or fins or other structures to increase the surface area as noted above with respect to FIG. 2. Disposed on heat transfer enhancement structure 450 is heat transfer enhancement structure 460 of a porous coating such as described above with reference to FIG. 3. In this embodiment, heat transfer enhancement structure 460 of a porous coating is shown directly on an entirety of heat transfer enhancement structure 450. It is appreciated that the entirety of heat transfer enhancement structure 450 need not be blanketed with heat transfer enhancement structure 460.

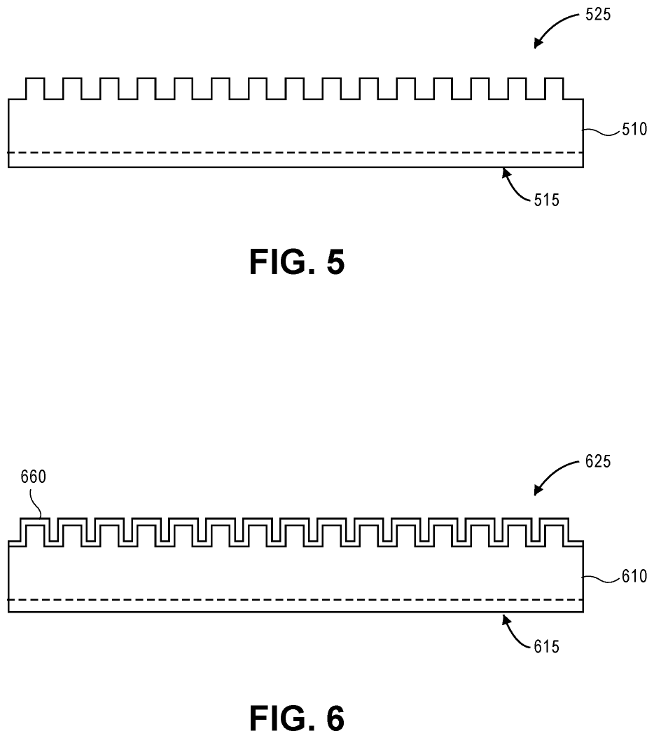

FIG. 5 shows another embodiment of an integrated circuit die. Die 510 includes device side 515 and backside 525. In this embodiment, backside 525 of die 510 includes a heat enhancement configuration therein. In this embodiment, the heat enhancement configuration is a plurality of pillars or fins formed into a backside of the die. Where die 510 is a semiconductor material such as silicon, the heat enhancement configuration in backside 525 may be formed by, for example, a mask and etch process.

FIG. 6 shows a further embodiment of a die. Die 610 includes device side 615 and backside 625. Backside 625 includes a heat enhancement configuration formed therein as illustrated in the plurality of pillars or fins. Disposed on the heat enhancement configuration in backside 625 is heat transfer enhancement structure 660 of, for example, a microporous coating such as described above with respect to FIG. 3.

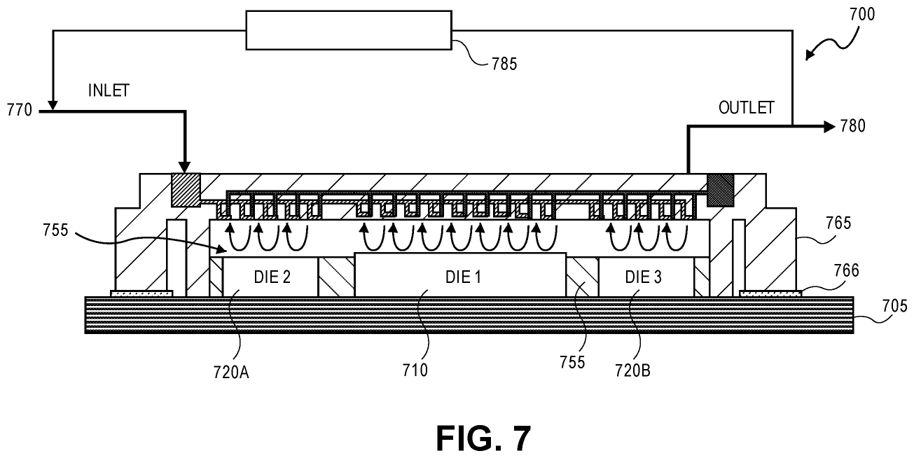

FIG. 7 shows an embodiment of an integrated circuit assembly. Assembly 700 includes a multi-chip package including package substrate 705 to which die 710, die 720A and die 720B are connected in a device side down orientation (device side facing package substrate 705). In one embodiment, at least one of die 710, die 720A and die 720B includes a die backside including a heat transfer enhancement configuration formed therein or a heat transfer enhancement structure formed thereon or some combination of a heat transfer enhancement configuration and a heat transfer enhancement structure.

Overlying die 710, die 720A and die 720 of package substrate 705 is lid 765. Lid 765 contains the dies within an enclosed volume or cavity. In one embodiment, lid 765 is connected to package substrate 705 through adhesive 766. Lid 765, in one embodiment, may be a thermally conductive material such as a metal lid. FIG. 7 shows die 710, 720A and 720B within cavity 755. Each area between each die is surrounded by molding material leaving a backside of each die exposed in cavity 755.

In one embodiment, lid 765 includes a manifold for injection of a fluid into and removal of fluid from cavity 755. FIG. 7 shows manifold inlet 770 to introduce a fluid such as water into cavity 755 and manifold outlet 780 to remove the fluid from the cavity. In some embodiments, the cooling fluid is water, whereas in other embodiments, the fluid may be a mixture of water and antifreeze, refrigerant, alcohol, inert fluorinated hydrocarbon, helium, and/or other suitable cooling fluid (either liquid or gas). The removed fluid may be directed to heat exchanger 785 before being re-circulated into cavity 755 through inlet 770. Because each one or more of die 710, die 720A and die 720B includes a backside including heat transfer enhancement configuration formed therein and/or a heat transfer enhancement structure formed thereon, a heat transfer area is maximized relative to a die backside that is planar. Thus, in this manner, the heat transfer area associated with each die or a boiling nucleation site density is increased.

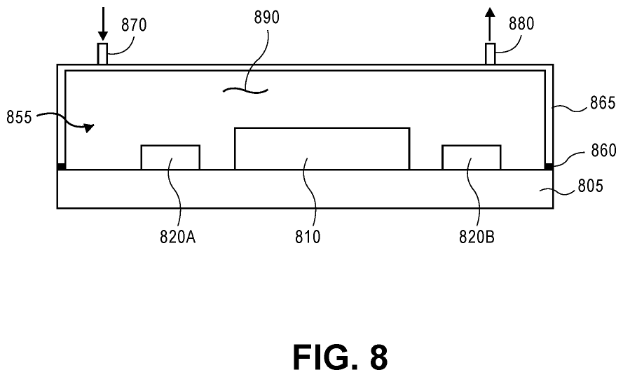

FIG. 8 shows another embodiment of an integrated circuit assembly. Integrated circuit assembly includes package substrate 805 to which each of die 810, die 820A and die 820B are connected in a device side down orientation. Overlying die 810, die 820A and die 820B, in this embodiment, is lid 865. Lid 865 is connected to package substrate 805 in a manner to define a cavity or volume around and over the die. Lid 865 is connected to package substrate 805 by adhesive 860. Disposed within cavity or volume 855 defined by lid 865 on package substrate 805 is fluid 890 such as water or other fluid as described in the previous paragraph. The fluid surrounds each of die 810, die 820A and die 820B. In one embodiment, one or more die 810, die 820A and die 820B includes at least one of a heat enhancement configuration formed therein and/or a heat transfer enhancement structure formed thereon. Reference is made with regard to the embodiments of FIGS. 2-6 described above. The heat enhancement configuration or heat transfer enhancement structure increases thermal performance of the die (increased heat transfer away from the die) relative to a generally planar bare backside surface. In one embodiment, a jetting configuration may be added to the integrated circuit assembly. Representatively, lid 865 includes inlet 870 and outlet 880. In one embodiment, an air jet or air may be introduced into volume 855 (e.g., compressed air) to improve the circulation of fluid 890 such as water within cavity or volume 855.

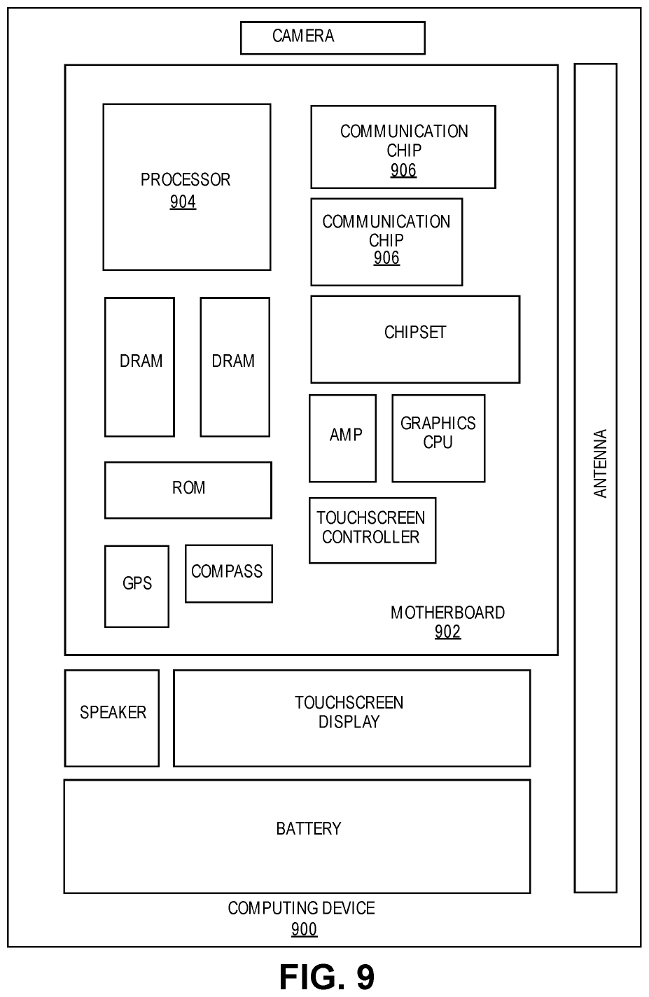

FIG. 9 illustrates computing device 900 in accordance with one implementation. Computing device 900 houses board 902. Board 902 may include a number of components, including but not limited to processor 904 and at least one communication chip 906. Processor 904 is physically and electrically coupled to board 902. In some implementations at least one communication chip 906 is also physically and electrically coupled to board 902. In further implementations, communication chip 906 is part of processor 904.

Depending on its applications, computing device 900 may include other components that may or may not be physically and electrically coupled to board 902. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

Communication chip 906 enables wireless communications for the transfer of data to and from computing device 900. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Communication chip 906 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. Computing device 900 may include a plurality of communication chips 906. For instance, first communication chip 906 may be dedicated to shorter range wireless communications such as Wi-Fi and Bluetooth and second communication chip 906 may be dedicated to longer range wireless communications such as GPS, EDGE, GPRS, CDMA, WiMAX, LTE, Ev-DO, and others.

Processor 904 of computing device 900 includes an integrated circuit die packaged within processor 904. In some implementations, the integrated circuit die of the processor includes one or more devices, such as transistors or metal interconnects, and a die backside that includes a heat transfer enhancement configuration formed therein or a heat transfer enhancement structure formed thereon. The term “processor” may refer to any device or portion of a device that processes electronic data from registers and/or memory to transform that electronic data into other electronic data that may be stored in registers and/or memory.

Communication chip 906 also includes an integrated circuit die packaged within communication chip 906. In accordance with another implementation, the integrated circuit die of the communication chip includes one or more devices, such as transistors or metal interconnects, and a die backside that includes a heat transfer enhancement configuration formed therein or a heat transfer enhancement structure formed thereon.

In further implementations, another component housed within computing device 900 may contain an integrated circuit die that includes one or more devices, such as transistors or metal interconnects.

In various implementations, computing device 900 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, computing device 900 may be any other electronic device that processes data.

### Examples

Example 1 is an integrated circuit die including a device side and a backside opposite the device side, wherein the backside includes at least one of a heat transfer enhancement configuration formed therein and a heat transfer enhancement structure formed thereon each of which enhance a heat transfer area or a boiling nucleation site density over a planar backside surface.

In Example 2, the backside of the integrated circuit die of Example 1 includes a heat transfer enhancement configuration formed therein and the heat transfer enhancement configuration includes a surface that has a greater surface area than a planar surface.

In Example 3, the surface of the integrated circuit die of Example 2 includes a plurality of fins.

In Example 4, the backside of the integrated circuit die of any of Examples 1-3 includes a heat transfer enhancement structure that is a thermally conductive material.

In Example 5, the thermally conductive material of the integrated circuit die of Example 4 includes a first surface coupled to the backside and an opposite second surface, wherein the second surface has a greater surface area than a planar surface.

In Example 6, the heat transfer enhancement structure of the integrated circuit die of any of Examples 1-5 includes a porous coating layer.

In Example 7, the porous coating layer of the integrated circuit die of Example 6 includes a material that is functionalized to increase a hydrophilicity of the layer.

In Example 8, the porous coating layer of the integrated circuit die of Example 6 is a first structure and the heat transfer enhancement structure further includes a second structure and the second structure includes a thermally conductive material including a first surface coupled to the backside and an opposite second surface, wherein the second surface has a greater surface area than a planar surface.

In Example 9, the porous coating layer of the integrated circuit die of Example 8 includes a material that is functionalized to increase a hydrophilicity of the layer.

Example 10 is an integrated circuit assembly including an integrated circuit die coupled to a substrate, the integrated circuit die including a device side and a backside opposite the device side, wherein the backside includes at least one of a heat transfer enhancement configuration formed therein and a heat transfer enhancement structure formed thereon each of which enhance a heat transfer area or a boiling nucleation site density over a planar backside surface; and a heat exchanger disposed partially or fully on the backside of the integrated circuit die.

In Example 11, the heat exchanger of the integrated circuit assembly of Example 11 includes a fluid operable to directly impinge on the backside of the integrated circuit die.

In Example 12, the backside of the integrated circuit die of the assembly of Example 11 includes a heat transfer enhancement configuration formed therein and the heat transfer enhancement configuration includes a surface that has a greater surface area than a planar surface.

In Example 13, the backside of the integrated circuit die of the assembly of Example 11 includes a heat transfer enhancement structure that is a thermally conductive material.

In Example 14, the thermally conductive material of the integrated circuit assembly of Example 13 includes a first surface coupled to the backside of the integrated circuit die and an opposite second surface, wherein the second surface has a greater surface area than a planar surface.

In Example 15, the backside of the integrated circuit die of the assembly of Example 11 includes a heat transfer enhancement structure that includes a porous coating layer.

In Example 16, the porous coating layer of the integrated circuit assembly of Example 15 includes a material that is functionalized to increase a hydrophilicity of the layer.

In Example 17, the porous coating layer of the integrated circuit assembly of Example 15 is a first structure and the heat transfer enhancement structure further includes a second structure and the second structure includes a thermally conductive material including a first surface coupled to the backside of the integrated circuit die and an opposite second surface, wherein the second surface has a greater surface area than a planar surface.

In Example 18, the integrated circuit die of the assembly of Example 10 is a first die, the integrated circuit assembly further including at least one second die, and wherein the heat exchanger is disposed partially or fully on the first die and the at least one second die.

Example 19 is a method of forming an integrated circuit assembly including disposing a heat exchanger on a multi-chip package, the multi-chip package including at least one integrated circuit die including a device side and an opposite backside, wherein the backside includes at least one of a heat transfer enhancement configuration formed therein and a heat transfer enhancement structure formed thereon each of which enhance a heat transfer area or a boiling nucleation site density over a planar backside surface; and contacting the backside of the at least one integrated circuit die with a fluid.

In Example 20, the fluid in the method of Example 19 is water.

In Example 21, the backside of the integrated circuit die in the method of Example 19 or 20 includes a heat transfer enhancement configuration formed therein and the heat transfer enhancement configuration includes a surface that has a greater surface area than a planar surface.

In Example 22, the backside of the at least one integrated circuit die in the methods of any of Examples 19-21 includes a heat transfer enhancement structure that includes a first surface coupled to the backside and an opposite second surface, wherein the second surface has a greater surface area than a planar surface.

In Example 23, the backside of the at least one integrated circuit die in the methods of any of Examples 19-22 includes a heat transfer enhancement structure that includes a porous coating layer.

In Example 24, the backside of the at least one integrated circuit die in the method of Example 19 or 20 includes each of a heat transfer enhancement configuration formed therein and a heat transfer enhancement structure formed thereon.

The above description of illustrated implementations, including what is described in the Abstract, is not intended to be exhaustive or to limit the invention to the precise forms disclosed. While specific implementations of, and examples for, the invention are described herein for illustrative purposes, various equivalent modifications are possible within the scope, as those skilled in the relevant art will recognize.

These modifications may be made to the invention in light of the above detailed description. The terms used in the following claims should not be construed to limit the invention to the specific implementations disclosed in the specification and the claims. Rather, the scope is to be determined entirely by the following claims, which are to be construed in accordance with established doctrines of claim interpretation.

1. An integrated circuit die comprising:
a device side and a backside opposite the device side, wherein the backside comprises at least one of a heat transfer enhancement configuration formed therein and a heat transfer enhancement structure formed thereon each of which enhance a heat transfer area or a boiling nucleation site density over a planar backside surface.

2. The integrated circuit die of claim 1, wherein the backside comprises a heat transfer enhancement configuration formed therein and the heat transfer enhancement configuration comprises a surface that has a greater surface area than a planar surface.

3. The integrated circuit die of claim 2, wherein the surface comprises a plurality of fins.

4. The integrated circuit die of claim 1, wherein the backside comprises a heat transfer enhancement structure that is a thermally conductive material.

5. The integrated circuit die of claim 4, wherein the thermally conductive material comprises a first surface coupled to the backside and an opposite second surface, wherein the second surface has a greater surface area than a planar surface.

6. The integrated circuit die of claim 1, wherein the heat transfer enhancement structure comprises a porous coating layer.

7. The integrated circuit die of claim 6, wherein the porous coating layer comprises a material that is functionalized to increase a hydrophilicity of the layer.

8. The integrated circuit die of claim 6, wherein the porous coating layer is a first structure and the heat transfer enhancement structure further comprises a second structure and the second structure comprises a thermally conductive material comprising a first surface coupled to the backside and an opposite second surface, wherein the second surface has a greater surface area than a planar surface.

9. The integrated circuit die of claim 8, wherein the porous coating layer comprises a material that is functionalized to increase a hydrophilicity of the layer.

10. An integrated circuit assembly comprising:
an integrated circuit die coupled to a substrate, the integrated circuit die comprising a device side and a backside opposite the device side, wherein the backside comprises at least one of a heat transfer enhancement configuration formed therein and a heat transfer enhancement structure formed thereon each of which enhance a heat transfer area or a boiling nucleation site density over a planar backside surface; and
a heat exchanger disposed partially or fully on the backside of the integrated circuit die.

11. The integrated circuit assembly of claim 10, wherein the heat exchanger comprises a fluid operable to directly impinge on the backside of the integrated circuit die.

12. The integrated circuit assembly of claim 11, wherein the backside of the integrated circuit die comprises a heat transfer enhancement configuration formed therein and the heat transfer enhancement configuration comprises a surface that has a greater surface area than a planar surface.

13. The integrated circuit assembly of claim 11, wherein the backside of the integrated circuit die comprises a heat transfer enhancement structure that is a thermally conductive material.

14. The integrated circuit assembly of claim 13, wherein the thermally conductive material comprises a first surface coupled to the backside of the integrated circuit die and an opposite second surface, wherein the second surface has a greater surface area than a planar surface.

15. The integrated circuit assembly of claim 11, wherein the backside of the integrated circuit die comprises a heat transfer enhancement structure that comprises a porous coating layer.

16. The integrated circuit assembly of claim 15, wherein the porous coating layer comprises a material that is functionalized to increase a hydrophilicity of the layer.

17. The integrated circuit assembly of claim 15, wherein the porous coating layer is a first structure and the heat transfer enhancement structure further comprises a second structure and the second structure comprises a thermally conductive material comprising a first surface coupled to the backside of the integrated circuit die and an opposite second surface, wherein the second surface has a greater surface area than a planar surface.

18. The integrated circuit assembly of claim 10, wherein the integrated circuit die is a first die, the integrated circuit assembly further comprising at least one second die, and wherein the heat exchanger is disposed partially or fully on the first die and the at least one second die.

19. A method of forming an integrated circuit assembly comprising:
disposing a heat exchanger on a multi-chip package, the multi-chip package comprising at least one integrated circuit die comprising a device side and an opposite backside, wherein the backside comprises at least one of a heat transfer enhancement configuration formed therein and a heat transfer enhancement structure formed thereon each of which enhance a heat transfer area or a boiling nucleation site density over a planar backside surface; and
contacting the backside of the at least one integrated circuit die with a fluid.

20. The method of claim 19, wherein the backside of the integrated circuit die comprises a heat transfer enhancement configuration formed therein and the heat transfer enhancement configuration comprises a surface that has a greater surface area than a planar surface.

21. The method of claim 19, wherein the backside of the at least one integrated circuit die comprises a heat transfer enhancement structure that comprises a first surface coupled to the backside and an opposite second surface, wherein the second surface has a greater surface area than a planar surface.

22. The method of claim 19, wherein the backside of the at least one integrated circuit die comprises a heat transfer enhancement structure that comprises a porous coating layer.
